(19) United States
(12) Patent Application Publication
(10) Pub. No.: US 2025/0062118 A1
(43) Pub. Date: Feb. 20, 2025

(54) HIGH PRESSURE PLASMA INHIBITION

(71) Applicant: Lam Research Corporation, Fremont, CA (US)

(72) Inventors: Dustin Zachary Austin, Tigard, OR (US); Joseph R. Abel, West Linn, OR (US); Aaron R. Fellis, Lake Oswego, OR (US); Douglas Walter Agnew, Portland, OR (US); Bart J. Van Schravendijk, Palo Alto, CA (US)

(21) Appl. No.: 18/720,146

(22) PCT Filed: Dec. 14, 2022
(86) PCT No.: PCT/US2022/081591

§ 371 Date: Jun. 14, 2024

Related U.S. Application Data
(60) Provisional application No. 63/265,690, filed on Dec. 17, 2021.

(51) Int. Cl. H01L 21/02; C23C 16/04; C23C 16/50; H01J 37/32

(52) U.S. Cl. CPC H01L 21/02315; C23C 16/04; C23C 16/50; H01J 37/32816; H01L 21/0228

(57) ABSTRACT

Methods of filling a gap with a dielectric material including using an inhibitor plasma during deposition. When the inhibitor plasma interacts with material in the feature, the material at the bottom of the feature receives less plasma treatment than material located closer to a top portion of the feature or in field. Deposition at the top of the feature is then selectively inhibited and deposition in lower portions of the feature proceeds with less inhibition or without being inhibited. As a result, bottom-up fill is enhanced, which can create a sloped profile that mitigates the seam effect and prevents void formation. In some embodiments, the inhibitor plasma is used at a higher pressure to increase the rate of inhibition, improving throughput.

### INCORPORATED BY REFERENCE

An application data sheet is filed concurrently with this specification as part of the present application. Each application that the present application claims benefit of or priority to as identified in the concurrently filed application data sheet is incorporated by reference herein in its entirety and for all purposes.

### BACKGROUND

Many semiconductor device fabrication processes involve formation of films including silicon-containing films such as silicon oxide or silicon nitride. Plasma enhanced atomic layer deposition (ALD) may be used to deposit silicon-containing films. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing films in structures. In one aspect of the embodiments herein, a method of depositing a film is provided, the method including: providing a substrate having a structure including a gap to be filled in a process chamber; and performing one or more cycles of: (a) exposing the substrate to a plasma including a first gas to inhibit deposition on a portion of the gap, wherein the pressure of the process chamber during (a) is at least about 3 Torr; and (b) after (a), depositing dielectric material in the gap. In some embodiments, the gap has an aspect ratio between about 3:1 and about 7:1. In some embodiments, the gap has an aspect ratio of at least about 150:1. In some embodiments, the gap has a depth of at least about 1 μm. In some embodiments, the pressure of the process chamber during (a) is at least about 15 Torr. In some embodiments, the duration of (a) is less than about 30 seconds. In some embodiments, the duration of (a) is less than about 15 seconds. In some embodiments, the first gas includes a non-halogen-containing species. In some embodiments, the first gas includes a nitrogen-containing species. In some embodiments, the nitrogen-containing species is N₂. In some embodiments, the first gas includes a halogen-containing species. In some embodiments, the halogen-containing species is a fluorine-containing species. In some embodiments, the halogen-containing species is a chlorine-containing species. In some embodiments, the halogen-containing species is nitrogen trifluoride (NF₃). In some embodiments, the first gas includes an amine-containing species. In some embodiments, the first gas includes a hydrogen-containing species. In some embodiments, depositing dielectric material during (b) includes an atomic layer deposition (ALD) process.

In another aspect of the embodiments herein, a method of depositing a film is provided, the method including: providing a substrate having a structure including a gap to be filled in a process chamber, wherein the gap has an aspect ratio between about 3:1 and about 7:1; and performing one or more cycles of: (a) exposing the substrate to a plasma including N₂ to inhibit deposition on a portion of the gap, wherein the pressure of the process chamber during (a) is at least about 3 Torr, and wherein a duration of (a) is less than about 30 seconds; and (b) after (a), depositing dielectric material in the gap.

These and other features of the disclosed embodiments will be described in detail below with reference to the associated drawings.

### BRIEF DESCRIPTION OF DRAWINGS

FIG. 1 is a process flow diagram depicting operations for a method in accordance with disclosed embodiments.

FIGS. 2A-C show illustrations of an example of filling gaps in accordance with disclosed embodiments.

FIG. 3 shows an example of a process sequence that may be used in accordance with the disclosed embodiments.

FIG. 4 is a process flow diagrams depicting operations for a method in accordance with disclosed embodiments.

FIGS. 5-8 are schematic diagrams of example process stations for performing disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibitor plasma during atomic layer deposition (ALD) of dielectric material in gaps that facilitates void-free bottom gapfill. The inhibitor plasma creates a passivated surface and increases a nucleation barrier of the deposited ALD film. When the inhibitor plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, button-up fill is enhanced, which creates a more favorable sloped profile that migrates the seam effect and prevents void formation. Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂).

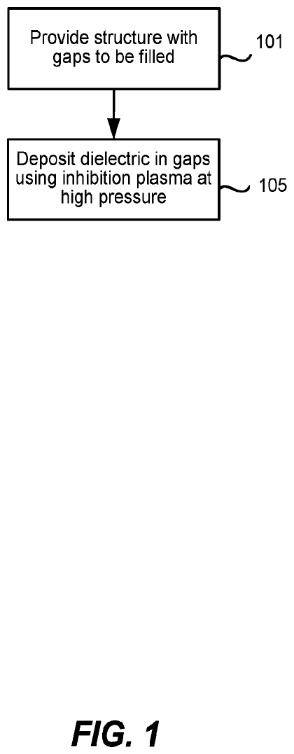

FIG. 1 is a process flow diagram that illustrates a method of filling gaps with dielectric material. The method begins with providing a structure with one or more gaps to be filled. (101). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gapfill other substrates, such as glass, plastic, and the like, including in the fabrication of microelectromechanical system (MEMS) devices.

Examples of structures include 3D NAND structures, DRAM structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. In another example, structures may include lateral/tunnel structures that extend horizontally from a common vertical trench. Other examples of sidewall materials include oxides, metals, and semiconducting materials. The methods described herein are not limited to a particular class of sidewall material and may be used to inhibit any susceptible material. The structure may be provided to a deposition chamber for deposition of a protective liner. The deposition chamber may be the same chamber as the subsequent dielectric deposition or a different chamber.

Dielectric material is deposited in the gaps using an inhibition plasma at high pressure. (105). As discussed further below, this can involve cycles of inhibition plasma followed by ALD of the dielectric film. High pressure may increase the inhibition effective depth and decrease the duration of an inhibition plasma treatment, improving throughput.

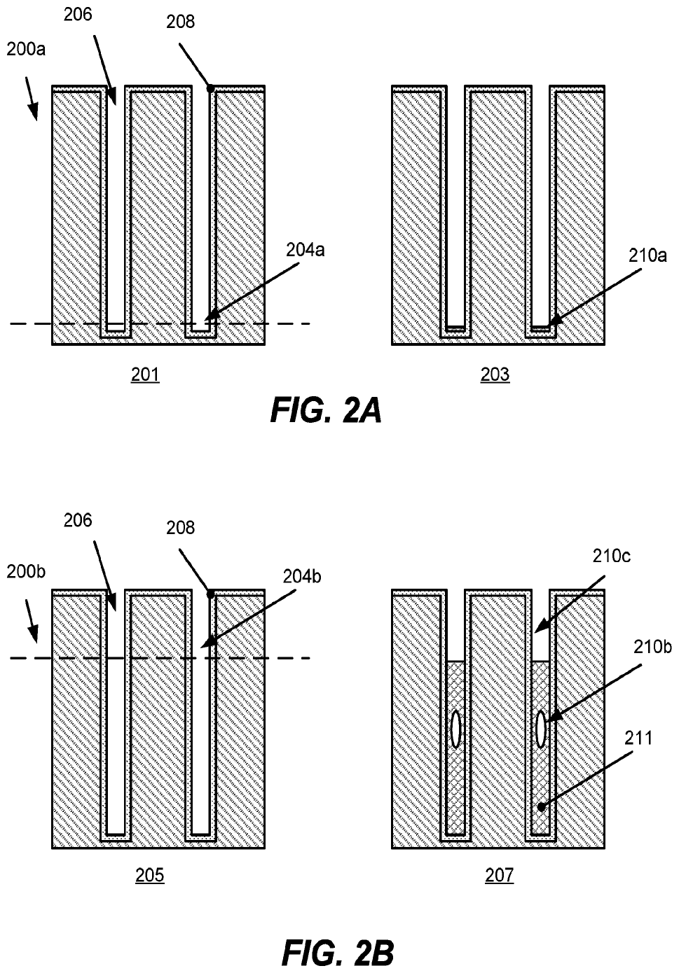

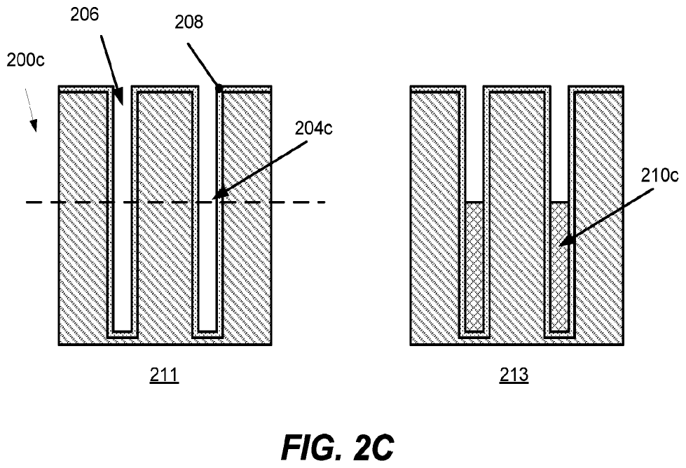

FIG. 2A shows an example of a structure 200a during various stages of a gap fill method described herein. At 201, the structure 200a is shown with gaps 206 to be filled with a dielectric material. In the example of FIG. 2A, the gaps 206 are formed between structures that may include dielectric, conducting, or semi-conducting material. In some embodiments, structure 200a is a low aspect ratio structure. In some embodiments, low aspect ratio structures may be structures having an aspect ratio between about 3:1 and about 7:1. In some embodiments, low aspect ratio structures may have a depth of at least about 1 μm. In the example of FIG. 2A, a conformal layer 208 is provided, which may be a liner deposited prior to deposition using an inhibition plasma. The conformal layer may protect the underlying layer from unwanted etch during a subsequent inhibition plasma treatment. In some embodiments, the conformal layer is a silicon nitride layer. In some embodiments, the conformal layer is a silicon oxide layer. In some embodiments, the conformal layer is a metal oxide layer, e.g., titanium oxide, zirconium oxide, tin oxide, hafnium oxide, or combinations thereof. In some embodiments the conformal layer is a silicon layer, e.g., poly Si. In some embodiments a conformal layer is not present.

At 201 the structure 200a may also be characterized by an inhibition effective depth (IED) line 204a (as shown by the dashed line). Inhibition plasma treatment may be characterized by an IED, which is the depth in a gap above which deposition is inhibited as a result of the inhibition plasma passivating the surface. The IED may be affected by multiple parameters, including the particular species used, a duration of the inhibition plasma treatment, plasma power, proportion of gas flow that is the species (rather than a carrier gas such as an inert gas, e.g., helium or argon), and pressure. In particular, the species used for inhibition may have a large effect on the IED. For example, plasmas generated from nitrogen trifluoride (NF₃) may be up to 100 times more effective than molecular nitrogen (N₂) for passivating a surface. For high aspect ratio and deep structures, e.g., at least about 100:1 and 3 μm or greater structures, NF₃ is an ideal choice of species for inhibition to sufficiently inhibit the structure to avoid pinch off, while also not fully inhibiting the structure. However, for lower aspect ratio and/or shallower structures, halogen-containing inhibition gases may be unsuitable as they may fully inhibit the structure, even when performed at a high dilution, short duration, and low power (each of which decreases the inhibition effect of an inhibition plasma treatment). Non-halogen-containing species, such as N₂, by contrast, does not passivate the surface as well as NF₃ or other halogen-containing species, having a much smaller IED even with lengthy plasma inhibition treatments that slow down throughput, which is undesirable. For example, a 0.5 second plasma inhibition treatment with NF₃ may fully inhibit a structure that is only partially inhibited by a 60 second plasma inhibition treatment using N₂.

Returning to FIG. 2A, IED line 204a is near the bottom of the feature, indicating complete inhibition of the gaps 206. This may occur when using an inhibition plasma with a halogen-containing species when the structure has a low aspect ratio and/or depth. At 203, the gaps 206 are filled with dielectric material 210a in a bottom-up manner, such that there is relatively little or no deposition on the sidewalls above the IED line. This is due to the inhibition plasma. However, as the IED line is too close to the bottom of the feature, the gaps do not fill with dielectric material. For some aspect ratios and depths, an inhibition plasma using a halogen-containing species may be limited in decreasing the IED.

Conversely, FIG. 2B illustrates structure 200b that has gaps 206. At 205, structure 200b has an IED line 204b. IED line 204b is higher up in the feature (i.e. at a lesser depth) than IED line 204a. IED line 204b may be a result of treating structure 200c with an inhibition plasma without a halogen-containing species, e.g., N₂. At 207, the gaps 206 are filled with dielectric material 210b in a bottom-up manner, such that there is relatively little or no deposition on the sidewalls above the fill line. This is due to the inhibition plasma. However, voids 211 form in dielectric material 210b. These voids may result from the IED being too high in the feature, such that deposition above the location of the voids 211 causes a pinch-off that results in voids 211.

FIG. 2C illustrates a structure 200c that has gaps 206. At 211, structure 200c has an IED line 204c. IED line 204c is at a depth between IED line 204a and IED line 204b. In some embodiments, IED line 204c may be a result of treating structure 200b with an inhibition plasma according to various embodiments herein. At 213, the gaps 206 are filled with dielectric material 210c in a bottom-up manner, such that there is relatively little or no deposition on the sidewalls above the fill line. In particular, dielectric material 210c does not have voids.

As illustrated by FIGS. 2A and 2B, for some aspect ratios and depths, inhibition plasma treatment may result in over-inhibition or under-inhibition, such that deposition does not sufficiently occur or results in voids, respectively. In particular, inhibition plasma treatment using non-halogen-containing species such as N₂ may under-inhibit low aspect ratio structures, such as structures having an aspect ratio between about 3:1 and about 7:1. In some embodiments, low aspect ratio structures may have a depth of at least about 1 μm. In some embodiments the IED for inhibition plasma treatments using non-halogen-containing species such as N₂ may be increased by increasing the duration of the plasma treatment. However, the duration of the treatment may unacceptably increase throughput. For example, an inhibition plasma treatment using N₂ may increase the IED by treating the substrate for e.g., 60 seconds or more. When repeated over many cycles may significantly increase the time required to fill the feature. In some embodiments, even a 60 second plasma treatment with N₂ may not have a sufficient IED, resulting in voids as the feature is filled. As better inhibitors, such as halogen-containing species, may over-inhibit the structure, there are aspect ratios where prior inhibition plasma treatments do not have an IED that allows for fill without voids.

To address this concern, in some embodiments the inhibition plasma treatment may be performed at high pressure. High pressure refers to the pressure of the process chamber during the inhibition plasma treatment. High pressure may increase the effectiveness of the inhibition plasma, particularly for less effective inhibitors such as non-halogen-containing inhibition species, including non-halogen containing, nitrogen-containing species such as N₂. In some embodiments, non-halogen-containing inhibition species may include amines, with examples including NH₃, methylamine, dimethylamine, and trimethylamine. In some embodiments, non-halogen-containing species may include hydrazine. At high pressure, the duration of an inhibition plasma treatment may be significantly reduced without reducing the IED or even increasing the IED when compared to a low pressure inhibition plasma treatment. In some embodiments, a high pressure inhibition plasma treatment refers to a pressure of more than about 6 Torr, at least about 10 Torr, at least about 15 Torr, at least about 20 Torr, between about 10 Torr and about 30 Torr, or between about 15 Torr and 30 Torr.

High pressure inhibition plasma treatment may be particularly advantageous for inhibition plasma treatments using non-halogen-containing species, which typically have a significantly lower inhibition effect compared to halogen-containing species. As noted above, an inhibition plasma treatment using NF₃ may be performed for as little as 0.5 seconds. Thus, increasing the pressure of an NF₃ inhibition plasma may fully inhibit the structure for low aspect ratio structures regardless of other processing parameters that would decrease the inhibition effect (shorter duration, dilution with inert gas, low plasma power). By contrast, a non-halogen-containing species, such as N₂, may be used for inhibition plasma treatments of between about 10 seconds and about 60 seconds. Performing an inhibition plasma treatment using N₂ at high pressure may decrease the duration of the inhibition plasma treatment to achieve a particular IED from about 60 seconds (at a lower pressure, e.g., 6 Torr) to about 20 seconds or less at high pressure.

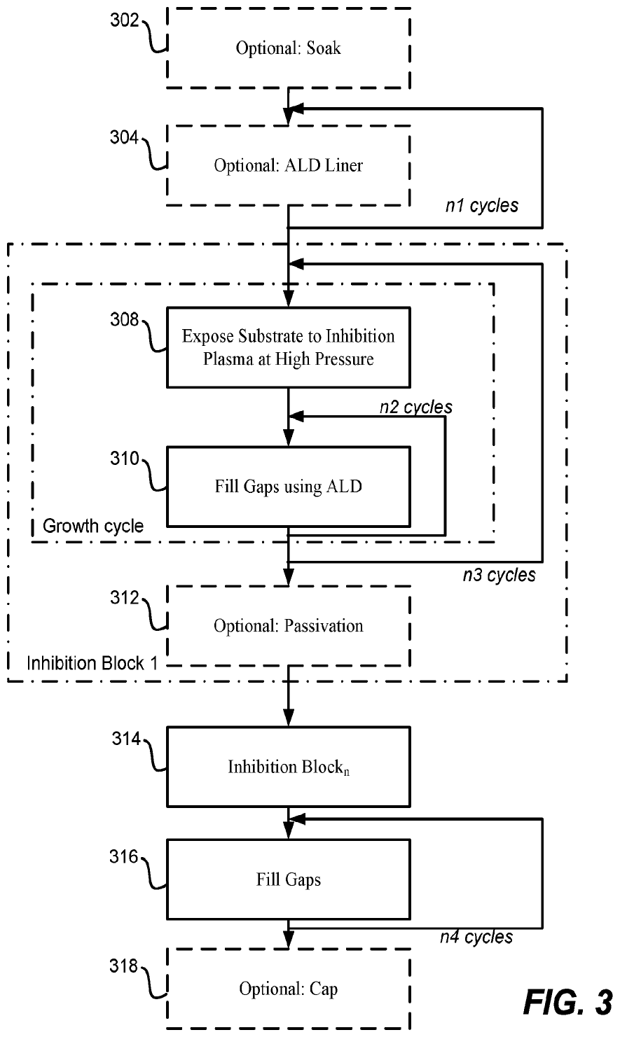

FIG. 3 shows an example of a process sequence that may be used in accordance with the disclosed embodiments. The process sequence in FIG. 3 include treating a substrate with an inhibition plasma at high pressure. Other operations (e.g., soak, passivation) may be omitted in certain embodiments and operations may be added in certain embodiments. In the example process sequence of FIG. 3, one or more wafers undergo gap fill. The process may begin with a soak after being provided to a deposition chamber. (302). This can be useful, for example, to remove particles or other pretreatment. Then, n1 cycles of ALD deposition of a liner are performed. (304). Further details of a liner ALD are discussed below.

After the optional liner is deposited, n inhibition blocks are performed, with the operations of the first inhibition block (n=1) shown. The first operation is the inhibition plasma, which is a surface treatment. (308) As discussed above, the plasma may include halogen species including anion and radical species such as F⁻, Cl⁻, I⁻, Br⁻, fluorine radicals, etc. Other inhibition plasmas may be used. In some embodiments, the inhibition plasma is generated from non-halogen containing species, including nitrogen-containing, non-halogen-containing species. For example, plasmas generated from molecular nitrogen (N₂), molecular hydrogen (H₂), ammonia (NH₃), amines, diols, diamines, aminoalcohols, thiols, alkyl halides, halides, HF, fluorine-containing species, chlorine-containing species, iodine-containing species, or combinations thereof may be used as inhibition plasmas. In some embodiments, the inhibition plasma treatment is performed at high pressure as described herein.

When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. In FIG. 3, the next operation in the inhibition block is n2 cycles of ALD fill. (310). The dielectric material is deposited selectively at the bottom of the feature. The inhibition plasma and the n2 cycles of ALD fill together make a growth cycle. This can be repeated n3 times to continue filling the feature with intermittent inhibition operations when the inhibition effect diminishes. The number of growth cycles in an inhibition block may depend on the re-entrancy of the feature, i.e., if it narrows at one or more points from the bottom to the top of the feature. Features that exhibit more re-entrancy may use a longer inhibition time or multiple inhibition blocks. In the example of FIG. 3, the inhibition block ends with an optional passivation operation. (312). This is a surface treatment that removes residual inhibitor and can also densify the deposited film. In some embodiments, an oxygen plasma is used.

One or more additional inhibition blocks, including growth cycle and passivation, may be performed for a total of n inhibition blocks. (314). The number of inhibition blocks depends on how much material is used to fill the feature. Inhibition plasma, ALD, and passivation conditions may be changed from inhibition block to inhibition block to fill the feature. For example, an inhibition plasma duration may be 20 seconds until the bottom quarter of the feature is filled (inhibition block 1), then changed to 5 seconds for the middle 50% of the structure (inhibition block 2), etc. Each inhibition block may have a different IED, where process parameters for an inhibition plasma treatment for an inhibition block are changed to target a different IED. Each inhibition block may fill a portion of the feature below an IED of that inhibition block. In some embodiments, the chamber pressure may be decreased between inhibition blocks to reduce the IED for a subsequent inhibition block.

When the feature is nearly filled, inhibition may no longer be necessary, and the fill can be completed with n4 cycles of ALD fill. (316). In some embodiments, an optional cap or overburden layer of dielectric may then be deposited. (318). Plasma enhanced chemical vapor deposition (PECVD) may be used at this stage for a fast deposition.

ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

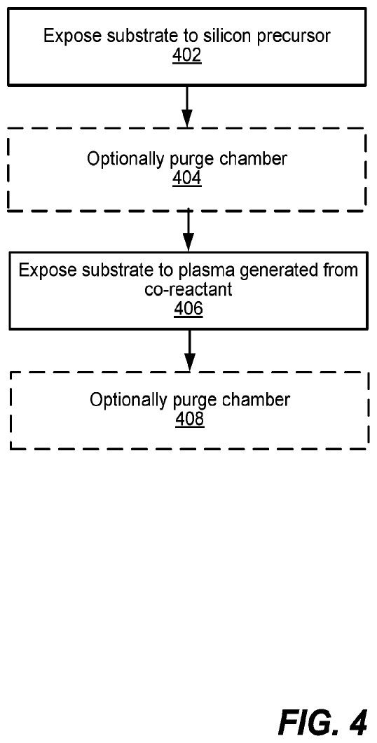

FIG. 4 presents a process flow diagram for a single plasma enhanced ALD cycle that may be implemented as part of operations 304, 310, and/or 316 shown in FIG. 3. In an operation 402, the substrate is exposed to a silicon-containing precursor, to adsorb the precursor onto the surface of the feature. This operation may be self-limiting. In some embodiments, the precursor adsorbs to less than all the active sites on the surface of the feature. In an operation 404, the process chamber is optionally purged to remove any unadsorbed silicon-containing precursors. In an operation 406, the substrate is exposed to a plasma generated from a co-reactant. Examples include O₂ and/or N₂O to form a silicon oxide layer or silicon oxynitride layer, N₂ or NH₃ to form a silicon nitride layer, methane (CH₄) to generate a silicon carbide layer etc. In operation 408, the process chamber is optionally purged to remove byproducts from the reaction between the silicon-containing precursor and the oxidant. Operations 402 through 408 repeated for a number of cycles to deposit the silicon-containing layer to a desired thickness in the feature.

It should be noted that the processes described herein are not limited to a particular reaction mechanism. Thus, the process described with respect to FIG. 3 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

In some embodiments, a high pressure inhibition plasma treatment refers to a pressure of more than about 6 Torr, at least about 10 Torr, at least about 15 Torr, at least about 20 Torr, between about 10 Torr and about 30 Torr, or between about 15 Torr and 30 Torr.

The duration of an inhibition plasma treatment may be between about 0.3 seconds and about 60 seconds, between about 0.3 seconds and about 30 seconds, at least about 0.3 seconds, at least about 1 second, at least about 5 seconds, at least about 10 seconds, at least about 20 seconds, or at least about 30 seconds. Inhibition plasma treatment using a halogen-containing species may generally be for a shorter duration than a non-halogen-containing species, as the halogen-containing species may more effectively passivate the surface compared to non-halogen-containing species.

High pressure inhibition plasma treatment may be used for various aspect ratios and structure depths. In some embodiments, high pressure inhibition plasma treatment may be used for low aspect ratio structures. A low aspect ratio structure may have an aspect ratio between about 3:1 and about 7:1, less than about 10:1, between about 3:1 and about 10:1, between about 3:1 and about 15:1, or less than about 15:1. A low aspect ratio structure may have a depth of at least about 100 nm, at least about 1 μm, at least about 2 μm, or at least about 3 μm.

In some embodiments, IED may be characterized by a percentage, e.g., 30% IED refers to an inhibition effective depth of 30% of the total depth of a feature. Thus, if a feature has a depth of 1 μm, a 30% IED means deposition would be inhibited along the sidewall surface of the feature that is within 300 nm from the top of the feature, with the remaining depth not being inhibited. In some embodiments, the IED of a high pressure inhibition plasma treatment according to embodiments described herein may be about 20%, about 30%, about 40%, about 50%, about 60%, or about 70%.

In some embodiments, a low aspect ratio structure may be inhibited using a high pressure inhibition plasma treatment using a non-halogen-containing species. In some embodiments, halogen-containing species may fully inhibit a low aspect ratio structure, even in a non-high pressure environment or when diluting the halogen-containing species by co-flowing an inert gas.

In some embodiments, a high pressure inhibition plasma treatment may be used with halogen-containing species for high aspect ratio features. In some embodiments, a high aspect ratio feature may have an aspect ratio of at least about 10:1, at least about 30:1, at least about 100:1, at least about 150:1, or at least about 180:1. In some embodiments, a depth of a high aspect ratio feature is at least about 3 μm.

In some embodiments, the flow of non-halogen-containing species, such as N₂, may be between about 10 slm and about 100 slm. In some embodiments, an inert gas may be co-flowed with the species used for inhibition. Inert gases may include helium, argon, xenon, or other gases that are non-reactive with the other species in the gas or surfaces of the substrate. The flow of inert gases, when used, may be between about 3.5 and about 15 slm. In some embodiments, oxygen- or hydrogen-containing species may be co-flowed with the species used for inhibition. If the species used for inhibition includes a nitrogen atom, the nitrogen atom may react with silicon-containing precursors or the silicon film to form silicon nitride. Adding oxygen- or hydrogen-containing species may inhibit conversion of silicon oxide or silicon to silicon nitride, respectively. In some embodiments, co-flows of oxygen- or hydrogen-containing species may be at least about 100 sccm, or between about 0 and about 5 slm.

In various embodiments, the plasma is an in-situ plasma, such that the plasma is formed directly above the substrate surface in the station. Example power per substrate areas for an in-situ plasma are between about 0.2122 W/cm² and about 2.122 W/cm² in some embodiments. For example, the power may range from about 1000 W to about 6000 W for a chamber processing four 300 mm wafers. In some embodiments, the power may be between about 2500 W and about 6000 W for four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

Methods described herein may be used for depositing various dielectric films. While processes described herein may refer to depositing silicon-containing films, in various embodiments other dielectric films may be deposited, including carbon-containing films, aluminum-containing films, lanthanum-containing films, hafnium-containing films, strontium-containing films, zirconium-containing films, or any combinations thereof. In some embodiments the dielectric film may be a high-k dielectric film, where a high-k value refers to a high dielectric constant, e.g., a dielectric constant higher than silicon dioxide.

For depositing silicon-containing films, one or more silicon-containing precursors may be used. In some examples, silicon-containing precursors can include silanes (e.g., SiH₄), polysilanes (H₃Si—(SiH₂)ₙ—SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ di-isopropylaminosilane (DIPAS), di-sec-butylaminosilane (DSBAS), SiH₂[N(CH₂CH₃)_{2]2} (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3 MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R⁴, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-see butylamino-1,1-dimethyl disiloxane, 1-N-methylethylamino-1,1-dimethyl disiloxane, 1-N methylpropylamino-1,1-dimethyl disiloxane 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CHSN), dimethylamine ((CH₃)₂NH), ethylamine (C₂H₅NH₂), isopropylamine (C₃H₉N), t-butylamine (C₄H₁₁N), di-t-butylamine (CH₁₉N), cyclopropylamine (C3H₅NH₂), sec-butylamine (C₄H₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

Where a deposited film includes carbon, a carbon-containing reactant may be used. Examples of carbon-containing reactants include, but are not limited to, hydrocarbons (CₓH_{y}) oxygen-containing hydrocarbons (CₓH_{y}O_{z}), carbonyl sulfide (COS), carbon disulfide (CS₂), fluorocarbons (CₓF_{y}), hydrofluorocarbons (CₓH_{y}F_{z}), etc.

Where a deposited film includes hafnium, a hafnium-containing reactant may be used. Examples of hafnium-containing reactants include, but are not limited to, Hafnium isopropoxide isopropanol adduct (C₁₂H₂₈HfO₄), Tetrakis(diethylamido)hafnium(IV) ([(CH₂CH₃)₂N]₄Hf), Tetrakis(ethylmethylamido)hafnium(IV) ([(CH₃)(C₂H₅)N]₄Hf), Tetrakis(dimethylamido)hafnium(IV) ([(CH₃)₂N]₄Hf), Hafnium(IV) n-butoxide (C₁₆H₃₆HfO₄), Hafnium(IV) tert-butoxide (Hf[OC(CH₃)₃]₄), Dimethylbis(cyclopentadienyl)hafnium(IV) ((C₅H₅)₂Hf(CH₃)₂), and Bis(trimethylsilyl)amidohafnium(IV) chloride ([[(CH₃)₃Si]2N]₂HfCl₂).

Where a deposited film includes strontium, a strontium-containing reactant may be used. Examples of strontium-containing reactants include, but are not limited to, Strontium isopropoxide (Sr(OCH(CH₃)₂)₂), Strontium acetate ((CH₃CO₂)₂Sr), Strontium tetramethylheptanedionate (C₂₂H₃₈O₄Sr), and Strontium acetylacetonate hydrate ([CH₃COCH═C(O—)CH₃]₂Sr·xH₂O).

Where a deposited film includes lanthanum, a lanthanum-containing reactant may be used. Examples of lanthanum-containing reactants include, but are not limited to, Lanthanum(III) acetate hydrate (La(CH₃CO₂)₃·xH₂O), Tris(cyclopentadienyl)lanthanum(III) (La(C₅H₅)₃), Lanthanum(III) acetylacetonate hydrate (La(C₅H₇O₂)₃·xH₂O), and Tris(tetramethylcyclopentadienyl)lanthanum(III) (C₂₇H₃₉La).

Where a deposited film includes zirconium, a zirconium-containing reactant may be used. Example zirconium-containing reactants include, but are not limited to, bis(cyclopentadienyl)zirconium(IV) dihydride (C₁₀H₁₂Zr); bis(methyl-η5-cyclopentadienyl)methoxymethylzirconium (Zr(CH₃C₅H₄)₂CH₃OCH₃); dimethylbis(pentamethylcyclopentadienyl)zirconium(IV) (C₂₂H₃₆Zr); tetrakis(diethylamido)zirconium(IV) ([(C₂H₅)₂N]₄Zr); tetrakis(dimethylamido)zirconium(IV) ([(CH₃N]₄Zr); tetrakis(ethylmethylamido)zirconium(IV) (Zr(NCH₃C₂H₅)₄);
zirconium(IV) dibutoxide(bis-2,4-pentanedionate) (C₁₈H₃₂O₆Zr); zirconium(IV) 2-ethylhexanoate (Zr(C₈H₁₅O₂)₄); zirconium tetrakis(2,2,6,6-tetramethyl-3,5-heptanedionate) (Zr(OCC(CH₃)₃CHCOC(CH₃)₃)₄), etc.

Where a deposited film includes aluminum, a aluminum-containing reactant may be used. Example aluminum-containing reactants include, but are not limited to, aluminum tris(2,2,6,6-tetramethyl-3,5-heptanedionate) (Al(OCC(CH₃)₃CHCOC(CH₃)₃)₃); triisobutylaluminum ([(CH₃)₂CHCH₂]₃Al); trimethylaluminum ((CH₃)₃Al); tris(dimethylamido)aluminum(III) (Al(N(CH₃)₂)₃), etc.

### Apparatus

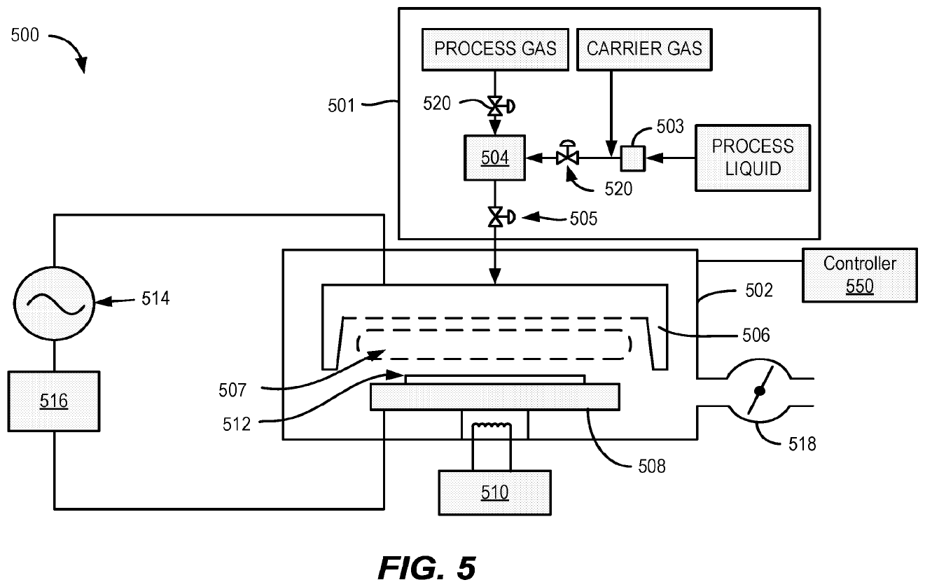

FIG. 5 schematically shows an embodiment of a process station 500 that may be used to deposit material using atomic layer deposition (ALD) and/or chemical vapor deposition (CVD), either of which may be plasma enhanced. For simplicity, the process station 500 is depicted as a standalone process station having a process chamber body 502 for maintaining a low-pressure environment. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers 550.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gasses to the showerhead 506. In some embodiments, an inhibitor or other gas may be directly delivered to the chamber body 502. One or more mixing vessel inlet valves 520 may control introduction of process gases to mixing vessel 504. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100° C. to approximately 150° C. at mixing vessel 504.

In some embodiments, liquid reactant may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller (LFC) upstream of vaporization point 503 may be provided for controlling a mass flow of liquid for vaporization and delivery to process station 500. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape, and may have any suitable number and arrangement of ports for distributing processes gases to substrate 512.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity and throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 and/or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process.

Optionally, pedestal 508 may be lowered and/or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of pedestal 508 may allow a plasma density to be varied during plasma activation and/or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Returning to the embodiment shown in FIG. 5, showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

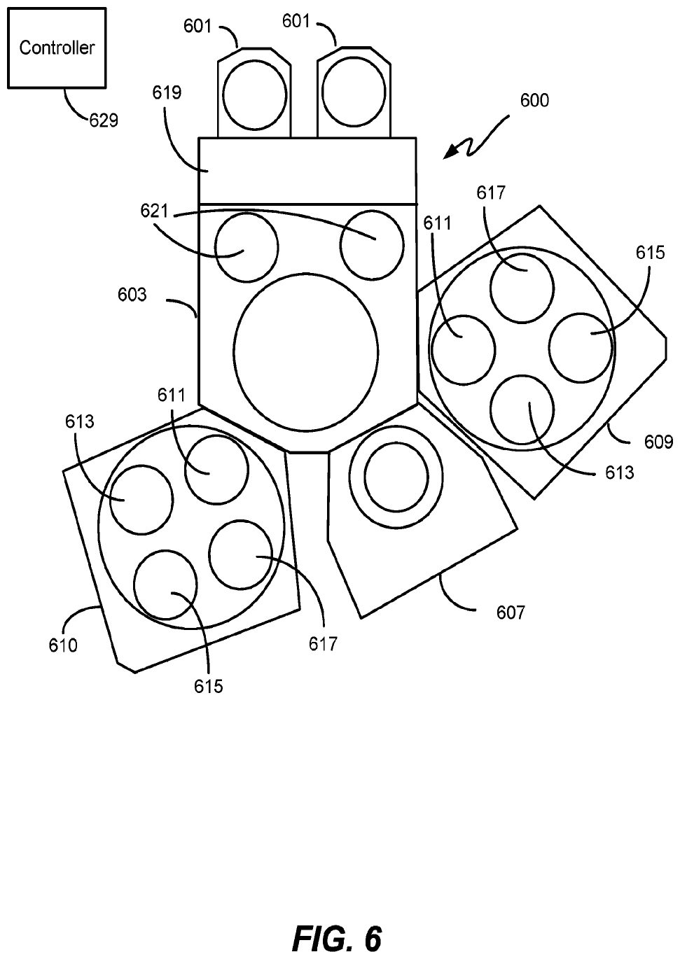

FIG. 6 is a block diagram of a processing system suitable for conducting thin film deposition processes in accordance with certain embodiments. The system 600 includes a transfer module 603. The transfer module 603 provides a clean, pressurized environment to minimize risk of contamination of substrates being processed as they are moved between various reactor modules. Mounted on the transfer module 603 are two multi-station reactors 609 and 610, each capable of performing atomic layer deposition (ALD) and/or chemical vapor deposition (CVD) according to certain embodiments. Reactors 609 and 610 may include multiple stations 611, 613, 615, and 617 that may sequentially or non-sequentially perform operations in accordance with disclosed embodiments. The stations may include a heated pedestal or substrate support, one or more gas inlets or showerhead or dispersion plate.

Also mounted on the transfer module 603 may be one or more single or multi-station modules 607 capable of performing plasma or chemical (non-plasma) pre-cleans, or any other processes described in relation to the disclosed methods. The module 607 may in some cases be used for various treatments to, for example, prepare a substrate for a deposition process. The module 607 may also be designed/configured to perform various other processes such as etching or polishing. The system 600 also includes one or more wafer source modules 601, where wafers are stored before and after processing. An atmospheric robot (not shown) in the atmospheric transfer chamber 619 may first remove wafers from the source modules 601 to loadlocks 621. A wafer transfer device (generally a robot arm unit) in the transfer module 603 moves the wafers from loadlocks 621 to and among the modules mounted on the transfer module 603.

In various embodiments, a system controller 629 is employed to control process conditions during deposition. The controller 629 will typically include one or more memory devices and one or more processors. A processor may include a CPU or computer, analog and/or digital input/output connections, stepper motor controller boards, etc.

The controller 629 may control all of the activities of the deposition apparatus. The system controller 629 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 629 may be employed in some embodiments.

Typically there will be a user interface associated with the controller 629. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 629. The signals for controlling the process are output on the analog and digital output connections of the system 600.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 550 or 629, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

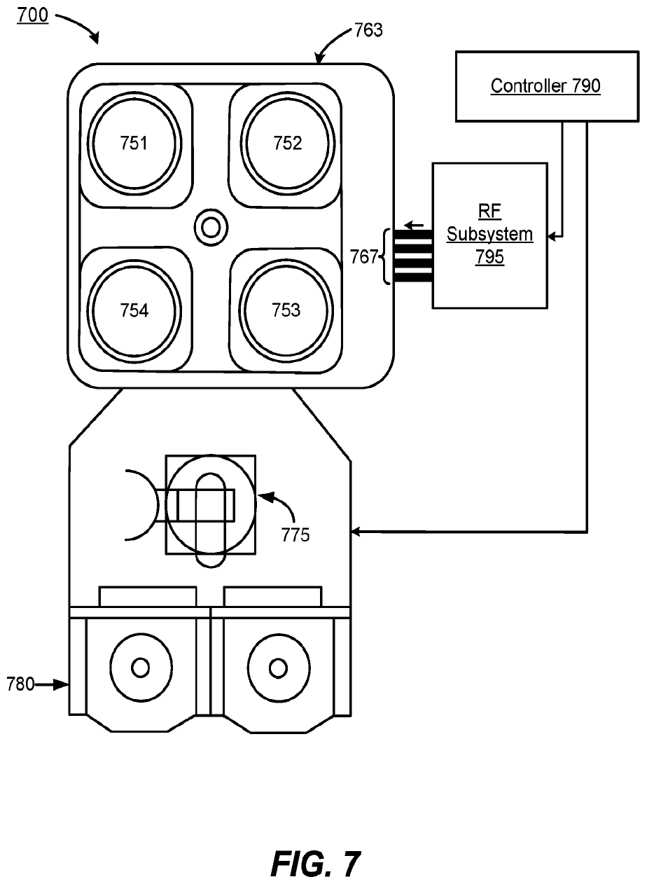

It may be appreciated that a plurality of process stations may be included in a multi-station processing tool environment, such as shown in FIG. 7, which depicts a schematic view of an embodiment of a multi-station processing tool. Processing apparatus 700 employs an integrated circuit fabrication chamber 763 that includes multiple fabrication process stations, each of which may be used to perform processing operations on a substrate held in a wafer holder, such as a pedestal, at a particular process station. In the embodiment of FIG. 7, the integrated circuit fabrication chamber 763 is shown having four process stations 751, 752, 753, and 754. Other similar multi-station processing apparatuses may have more or fewer process stations depending on the implementation and, for example, a desired level of parallel wafer processing, size/space constraints, cost constraints, etc. Also shown in FIG. 7 is substrate handler robot 775, which may operate under the control of system controller 790, configured to move substrates from a wafer cassette (not shown in FIG. 7) from loading port 780 and into integrated circuit fabrication chamber 763, and onto one of process stations 751, 752, 753, and 754.

FIG. 7 also depicts an embodiment of a system controller 790 employed to control process conditions and hardware states of processing apparatus 700. System controller 790 may include one or more memory devices, one or more mass storage devices, and one or more processors, as described herein.

RF subsystem 795 may generate and convey RF power to integrated circuit fabrication chamber 763 via radio frequency input ports 767. In particular embodiments, integrated circuit fabrication chamber 763 may comprise input ports in addition to radio frequency input ports 767 (additional input ports not shown in FIG. 7). Accordingly, integrated circuit fabrication chamber 763 may utilize 8 RF input ports. In particular embodiments, process stations 751-754 of integrated circuit fabrication chamber 763 may each utilize first and second input ports in which a first input port may convey a signal having a first frequency and in which a second input port may convey a signal having a second frequency. Use of dual frequencies may bring about enhanced plasma characteristics.

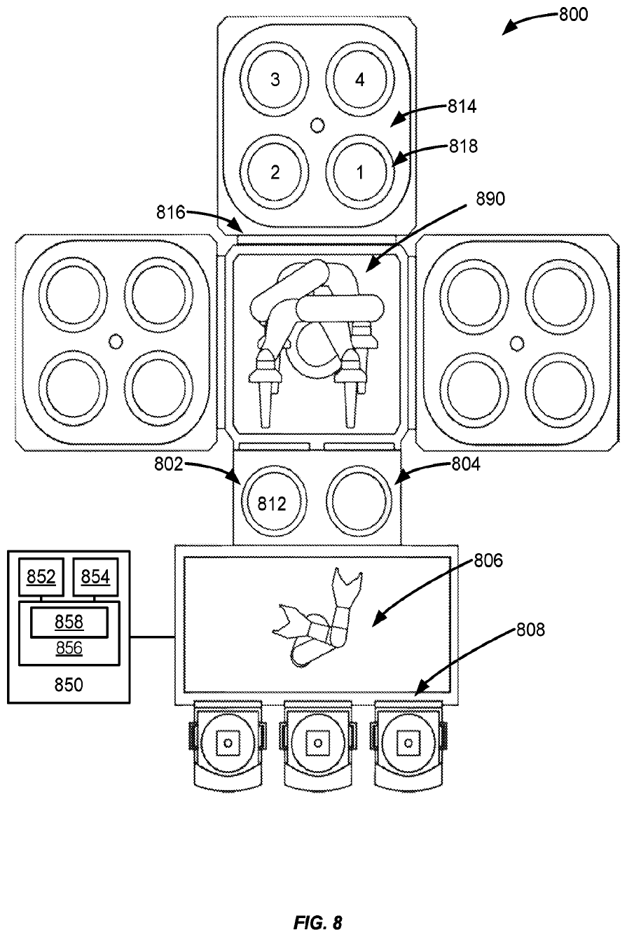

As described above, one or more process stations may be included in a multi-station processing tool. FIG. 8 shows a schematic view of an embodiment of a multi-station processing tool 800 with an inbound load lock 802 and an outbound load lock 804, either or both of which may comprise a remote plasma source. A robot 806, at atmospheric pressure, is configured to move substrates or wafers from a cassette loaded through a pod 808 into inbound load lock 802 via an atmospheric port. A substrate is placed by the robot 806 on a pedestal 812 in the inbound load lock 802, the atmospheric port is closed, and the load lock is pumped down. Where the inbound load lock 802 comprises a remote plasma source, the substrate may be exposed to a remote plasma treatment in the load lock prior to being introduced into a processing chamber 814. Further, the substrate also may be heated in the inbound load lock 802 as well, for example, to remove moisture and adsorbed gases. Next, a chamber transport port 816 to processing chamber 814 is opened, and the water handling system 890 places the substrate into the reactor on a pedestal of a first station shown in the reactor for processing. While the embodiment depicted in FIG. 8 includes load locks, it will be appreciated that, in some embodiments, direct entry of a substrate into a process station may be provided. In various embodiments, the soak gas is introduced to the station when the substrate is placed by the robot 806 on the pedestal 812.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 814 may include one or more matched pairs of ALD and plasma-enhanced ALD process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring substrates within processing chamber 814. In some embodiments, wafer handling system 890 may transfer substrates between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc. In some embodiments, system controller 850 includes machine-readable instructions for performing operations such as those described herein.

In some embodiments, system controller 850 controls the activities of process tool 800. System controller 850 executes system control software 858 stored in mass storage device 854, loaded into memory device 856, and executed on processor 852. Alternatively, the control logic may be hard coded in the system controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
providing a substrate having a structure including a gap to be filled in a process chamber; and
performing one or more cycles of:
(a) exposing the substrate to a plasma comprising a first gas to inhibit deposition on a portion of the gap, wherein the pressure of the process chamber during (a) is at least about 3 Torr; and
(b) after (a), depositing dielectric material in the gap.

2. The method of claim 1, wherein the gap has an aspect ratio between about 3:1 and about 7:1.

3. The method of claim 1, wherein the gap has an aspect ratio of at least about 150:1.

4. The method of claim 1, wherein the gap has a depth of at least about 1 μm.

5. The method of claim 1, wherein the pressure of the process chamber during (a) is at least about 15 Torr.

6. The method of claim 1, wherein a duration of (a) is less than about 30 seconds.

7. The method of claim 1, wherein a duration of (a) is less than about 15 seconds.

8. The method of claim 1, wherein the first gas comprises a non-halogen-containing species.

9. The method of claim 1, wherein the first gas comprises a nitrogen-containing species.

10. The method of claim 9, wherein the nitrogen-containing species is N₂.

11. The method of claim 1, wherein the first gas comprises a halogen-containing species.

12. The method of claim 11, wherein the halogen-containing species is a fluorine-containing species.

13. The method of claim 11, wherein the halogen-containing species is a chlorine-containing species.

14. The method of claim 11, wherein the halogen-containing species is nitrogen trifluoride (NF₃).

15. The method of claim 1, wherein the first gas comprises an amine-containing species.

16. The method of claim 1, wherein the first gas comprises a hydrogen-containing species.

17. The method of claim 1, wherein depositing dielectric material during (b) comprises an atomic layer deposition (ALD) process.

18. The method of claim 1, wherein the dielectric material comprises silicon, carbon, aluminum, lanthanum, hafnium, strontium, zirconium, or any combinations thereof.

19. A method, comprising:
providing a substrate having a structure including a gap to be filled in a process chamber, wherein the gap has an aspect ratio between about 3:1 and about 7:1; and
performing one or more cycles of:
(a) exposing the substrate to a plasma comprising N₂ to inhibit deposition on a portion of the gap, wherein the pressure of the process chamber during (a) is at least about 3 Torr, and wherein a duration of (a) is less than about 30 seconds; and
(b) after (a), depositing dielectric material in the gap.
